(19) United States
(12) Patent Application Publication
(10) Pub. No.: US 2026/0297342 A1
(43) Pub. Date: Oct. 1, 2026

(54) SURFACE TREATMENT LIQUID, AND SURFACE TREATMENT METHOD

(71) Applicant: TOKYO OHKA KOGYO CO, LTD., Kanagawa (JP)

(72) Inventors: Eita SUGA, Kanagawa (JP); Yuan-Chia CHANG, Hsinchu City (TW); Tomoya KUMAGAI, Kanagawa (JP)

(21) Appl. No.: 19/576,162

(22) Filed: Mar. 24, 2026

(30) Foreign Application Priority Data
Mar. 27, 2025 (JP) 2025-053643
Mar. 17, 2026 (JP) 2026-043520

(51) Int. Cl. C09D 7/20; B05D 5/08; C09D 4/00; C09D 5/00

(52) U.S. Cl. CPC C09D 7/20; B05D 5/08; C09D 4/00; C09D 5/00

(57) ABSTRACT

To provide a surface treatment liquid capable of satisfactorily hydrophobizing a surface of a substrate, which is for use for a surface treatment of the substrate, and a surface treatment method in which the surface of the substrate is treated using the surface treatment liquid. A surface treatment liquid for use for a hydrophobization treatment of a substrate includes a silylation agent and a solvent. The solvent contains water and propylene glycol monoalkyl ether acetate, and contains propylene glycol monoalkyl ether and/or propylene glycol monoacetate. A ratio of the mass of the silylation agent to the mass of the surface treatment liquid, a ratio of the mass of the propylene glycol monoalkyl ether acetate to the mass of the surface treatment liquid, a ratio of the masses/mass of the propylene glycol monoalkyl ether and/or the propylene glycol monoacetate to the mass of the surface treatment liquid, and a ratio of the mass of water to the mass of the surface treatment liquid are each set within a specific range.

This application is based on and claims the benefit of priority from Japanese Patent Application Nos. 2025-053643 and 2026-043520, respectively filed on 27 Mar. 2025 and 17 Mar. 2026, the contents of which are incorporated herein by reference.

### BACKGROUND OF THE INVENTION

### Field of the Invention

The present invention relates to a surface treatment liquid, and a surface treatment method.

### Related Art

In recent years, trends toward higher integration and miniaturization of semiconductor devices have grown, and thus progress toward refinement and higher aspect ratio of a resin pattern as an etching mask during etching a substrate and an inorganic pattern produced by etching processes has advanced. Meanwhile, however, a problem of so-called pattern collapse may occur. This pattern collapse is a phenomenon in which when a large number of resin patterns or inorganic patterns are formed on a substrate in parallel, adjacent patterns lean against each other, and in some cases, the patterns break from their base or peel off. Such pattern collapse can lead to reduction of product yield and reliability.

This pattern collapse is known to occur when a cleaning liquid is dried in a cleaning treatment after pattern formation, due to the surface tension of the cleaning liquid. In other words, when the cleaning liquid is removed in a drying step, stress based on the surface tension of the cleaning liquid acts between patterns, whereby pattern collapse occurs.

Therefore, many attempts have been made to prevent pattern collapse by adding a substance which reduces the surface tension to the cleaning liquid. For example, there have been proposed a cleaning liquid containing isopropyl alcohol added therein, a cleaning liquid containing a fluorine-based surfactant added therein and the like (see, for example, Patent Document 1)
Patent Document 1: Japanese Unexamined Patent Application Publication No. H6-163391

### SUMMARY OF THE INVENTION

However, the cleaning liquid devised in the way mentioned in Patent Document 1 has a problem that it does not sufficiently prevent pattern collapse.

Here, the method for preventing pattern collapse includes a method of making the surface of the pattern water-repellent so as to increase a contact angle of the cleaning liquid, in addition to a method of reducing the surface tension of the cleaning liquid. When patterns on a substrate are cleaned by the cleaning liquid, a force F acting between patterns is represented by the following formula (a). Here, γ represents the surface tension of the cleaning liquid, θ represents the contact angle of the cleaning liquid, A represents the aspect ratio of the pattern, and D represents the distance between pattern side walls.

$$F = 2 γ \cdot cos θ \cdot A / D \qquad ( a )$$

Therefore, when the surface of the pattern can be made water-repellent, and when the contact angle of the cleaning liquid can be increased (cos θ can be reduced), a force acting between patterns in the subsequent cleaning step can be reduced, and pattern collapse can be prevented.

The present invention has been made in view of the above problems, and an object thereof is to provide a surface treatment liquid capable of satisfactorily hydrophobizing a surface of a substrate, which is used for a surface treatment of the substrate, and a surface treatment method in which the surface of the substrate is treated using the surface treatment liquid.

The present inventors have found that the above-mentioned problem can be solved by a surface treatment liquid including a silylation agent and a solvent, which is used for a hydrophobization treatment of a substrate, in which propylene glycol monoalkyl ether acetate, propylene glycol monoalkyl ether and/or propylene glycol monoacetate, and water are contained in the solvent, and a ratio of the mass of the silylation agent to the mass of the surface treatment liquid, a ratio of the mass of the propylene glycol monoalkyl ether acetate to the mass of the surface treatment liquid, a ratio of the mass of the propylene glycol monoalkyl ether and/or propylene glycol monoacetate to the mass of the surface treatment liquid, and a ratio of the mass of water to the mass of the surface treatment liquid are respectively set within a specific range, thus completing the present invention. Specifically, the present invention provides the followings.

A first aspect of the present invention is directed to a surface treatment liquid for use for a hydrophobization treatment of a substrate, in which
the surface treatment liquid includes a silylation agent and a solvent,
the solvent includes water and propylene glycol monoalkyl ether acetate, and includes propylene glycol monoalkyl ether and/or propylene glycol monoacetate,
a ratio of the mass of the silylation agent to the mass of the surface treatment liquid is 1.000000% by mass or more and 20.000000% by mass or less,
a ratio of the mass of the propylene glycol monoalkyl ether acetate to the mass of the surface treatment liquid is 60.000000% by mass or more and 98.999800% by mass or less,
a ratio of the masses/mass of the propylene glycol monoalkyl ether and/or the propylene glycol monoacetate to the mass of the surface treatment liquid is 0.000100% by mass or more and 0.500000% by mass or less, and
a ratio of the mass of the water to the mass of the surface treatment liquid is 0.000100% by mass or more and 0.330000% by mass or less.

A second aspect of the present invention is directed to a surface treatment method including bringing the surface treatment liquid according to the first aspect into contact with a surface of a substrate to treat the surface of the substrate.

According to the present invention, it is possible to provide a surface treatment liquid capable of satisfactorily hydrophobizing a surface of a substrate, which is used for a surface treatment of the substrate, and a surface treatment method in which the surface of the substrate is treated using the surface treatment liquid.

### DETAILED DESCRIPTION OF THE INVENTION

### <Surface Treatment Liquid>

A surface treatment liquid is used for a hydrophobization treatment of a substrate. The surface treatment liquid includes a silylation agent and a solvent. The solvent includes water and propylene glycol monoalkyl ether acetate, and includes propylene glycol monoalkyl ether and/or propylene glycol monoacetate. A ratio of the mass of the silylation agent to the mass of the surface treatment liquid is 1.000000% by mass or more and 20.000000% by mass or less. A ratio of the mass of the propylene glycol monoalkyl ether acetate to the mass of the surface treatment liquid is 60.000000% by mass or more and 98.999800% by mass or less. A ratio of the masses/mass of the propylene glycol monoalkyl ether and/or the propylene glycol monoacetate to the mass of the surface treatment liquid is 0.000100% by mass or more and 0.500000% by mass or less. A ratio of the mass of the water to the mass of the surface treatment liquid is 0.000100% by mass or more and 0.330000% by mass or less. The surface treatment liquid may include various other components as required.

### [Substrate]

The substrate to be hydrophobized using the surface treatment liquid is not particularly limited. Examples of the substrate to be hydrophobized using the surface treatment liquid include substrates used in the production of semiconductor devices. Examples of the surface of the substrate to be hydrophobized using the surface treatment liquid include a surface of the substrate itself, surfaces of inorganic and resin patterns provided on the substrate, and surfaces of unpatterned inorganic and organic layers.

Examples of the inorganic pattern provided on the substrate include an inorganic pattern formed by producing an etching mask on the surface of an inorganic layer present on the substrate using a photoresist method, followed by an etching process. The inorganic layer is not particularly limited. Examples of the inorganic layer include an inorganic layer formed during the production process of a semiconductor device. Examples of the inorganic layer include a layer present on the substrate itself, a layer made of an oxide of an element constituting the substrate, and a layer made of inorganic substances such as silicon nitride, titanium nitride, and tungsten formed on the surface of the substrate.

Examples of the resin pattern provided on the substrate include a resin pattern formed on the substrate by a photoresist method. Such a resin pattern is formed, for example, by forming an organic layer which is a layer of a photoresist, on the substrate, exposing this organic layer through a photomask, followed by development. The organic layer is not particularly limited. Examples of the organic layer include an organic layer provided to form an etching mask during the production process of a semiconductor device. Examples of the organic layer include a layer on the surface of the substrate itself, and an organic layer provided on the surface of the substrate.

Essential or optional components included in the surface treatment liquid will be described hereinafter.

### [Silylation Agent]

The silylation agent is not particularly limited as long as the desired effect can be obtained. It is possible to use, as the silylation agent, any silylation agent which have been conventionally used to hydrophobize the surfaces of various articles without particular limitation. Suitable silylation agents include, for example, silylation agents represented by the following formulas (1) to (8) and cyclic silazane compounds.

(Silylation Agent represented by Formula (1))

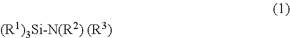

In formula (1), R¹ is a hydrogen atom, halogen atom or an organic group. A plurality of R¹ may be the same or different. The total number of carbon atoms in three R¹ is 1 or more. R² is a hydrogen atom or a chain hydrocarbon group. R³ is a hydrogen atom, a chain hydrocarbon group or a nonaromatic ring group. R² and R³ may be bonded to each other to form a ring.

In formula (1), R¹ is a hydrogen atom, a halogen atom, or an organic group. Examples of the halogen atom include a chlorine atom, a bromine atom, an iodine atom, and a fluorine atom. The organic group may include, in addition to a carbon atom, heteroatoms such as a nitrogen atom, an oxygen atom, and a sulfur atom.

In three R¹, the total number of carbon atoms and heteroatoms is not particularly limited as long as the total number of carbon atoms in three R¹ is 1 or more. In three R¹, the total number of carbon atoms and heteroatoms is preferably 1 or more and 10 or less, more preferably 1 or more and 8 or less, and still more preferably 1 or more and 3 or less.

As the organic group, a saturated or unsaturated chain hydrocarbon group, an aralkyl group, and an aromatic hydrocarbon group are preferred. Suitable examples of the saturated or unsaturated chain hydrocarbon group include a methyl group, an ethyl group, a vinyl group, an n-propyl group, an isopropyl group, an allyl group, a 1-propenyl group, an isopropenyl group, an n-butyl group, a sec-butyl group, a tert-butyl group, a 3-butenyl group, an n-pentyl group, an isopentyl group, a sec-pentyl group, a tert-pentyl group, an n-hexyl group, an n-heptyl group, an n-octyl group, an n-nonyl group, and an n-decyl group. Among these saturated or unsaturated chain hydrocarbon groups, a methyl group, an ethyl group, a vinyl group, an n-propyl group, and an allyl group are more preferred, and a methyl group, an ethyl group, and a vinyl group are still more preferred. Suitable examples of the aralkyl group include a benzyl group, a phenylethyl group, a phenylpropyl group, an α-naphthylmethyl group, and a β-naphthylmethyl group. Suitable examples of the aromatic hydrocarbon group include a phenyl group, an α-naphthyl group, and a β-naphthyl group.

In formula (1), R² is a hydrogen atom or a chain hydrocarbon group. The number of carbon atoms of the chain hydrocarbon group is not particularly limited. The number of carbon atoms of the chain hydrocarbon group is preferably 1 or more and 10 or less, more preferably 1 or more and 8 or less, and still more preferably 1 or more and 3 or less. The chain hydrocarbon group is a saturated or unsaturated chain hydrocarbon group. Suitable examples of the saturated or unsaturated chain hydrocarbon group are the same as the saturated or unsaturated chain hydrocarbon groups in the above-mentioned organic group.

In formula (1), R³ is a hydrogen atom, a chain hydrocarbon group, or a nonaromatic ring group. The chain hydrocarbon group is the same as the above-mentioned chain hydrocarbon groups.

Examples of the nonaromatic ring group include a saturated or unsaturated nonaromatic cyclic hydrocarbon group, and a nonaromatic heterocyclic group. The number of carbon atoms of the saturated or unsaturated nonaromatic cyclic hydrocarbon group is not particularly limited. The number of carbon atoms of the saturated or unsaturated nonaromatic cyclic hydrocarbon group is preferably 3 or more and 10 or less, more preferably 3 or more and 6 or less, and still more preferably 5 or 6. Suitable examples of the saturated or unsaturated nonaromatic cyclic hydrocarbon group include a cyclopropyl group, a cyclobutyl group, a cyclopentyl group, a cyclohexyl group, a cycloheptyl group, and a cyclooctyl group.

The heteroatom included in the nonaromatic heterocyclic group is not particularly limited. Examples of the heteroatom included in the nonaromatic heterocyclic group include a nitrogen atom, an oxygen atom, and a sulfur atom. The total number of carbon atoms and heteroatoms included in the nonaromatic heterocyclic group is not particularly limited. The total number of carbon atoms and heteroatoms included in the nonaromatic heterocyclic group is preferably 3 or more and 10 or less, more preferably 3 or more and 6 or less, and still more preferably 5 or 6. Suitable examples of the nonaromatic heterocyclic group include a pyrrolizin-1-yl group, a piperidin-1-yl group, a piperazin-1-yl group, morpholin-1-yl group, and a thiomorpholin-1-yl group.

In formula (1), R² and R³ may be bonded to each other to form a ring. The number of atoms included in the ring structure formed by bonding R² and R³ to each other is not particularly limited as long as the ring structure can be formed. The ring structure formed by bonding R² and R³ to each other is preferably from a three-membered ring to a ten-membered ring, and more preferably a five-membered ring or a six-membered ring. The ring structure formed by bonding R² and R³ to each other may include heteroatoms other than the nitrogen atom, such as an oxygen atom and a sulfur atom. Suitable examples of the ring structure formed by bonding R² and R³ to each other include nonaromatic heterocycles such as pyrrolidine, piperidine, piperazine, morpholine, and thiomorpholine; and aromatic heterocycles such as imidazole and triazole.

Specific examples of the silylation agent represented by the above formula (1) include N,N-dimethylaminotrimethylsilane, N,N-dimethylaminodimethylsilane, N,N-dimethylaminomonomethylsilane, N,N-diethylaminotrimethylsilane, tert-butylaminotrimethylsilane, allylaminotrimethylsilane, trimethylsilylacetamide, N,N-dimethylaminodimethylvinylsilane, N,N-dimethylaminodimethylpropylsilane, N,N-dimethylaminodimethyloctylsilane, N,N-dimethylaminodimethylphenylethylsilane, N,N-dimethylaminodimethylphenylsilane, N,N-dimethylaminodimethyl-tert-butylsilane, N,N-dimethylaminotriethylsilane, trimethylsilanamine, monomethylsilylimidazole, dimethylsilylimidazole, trimethylsilylimidazole, monomethylsilyltriazole, dimethylsilyltriazole, and trimethylsilyltriazole.

### (Silylation Agent Represented by Formula (2))

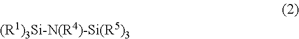

In the above formula (2), R¹ is the same as R¹ in the above formula (1). R⁴ is a hydrogen atom, a methyl group, a trimethylsilyl group, or a dimethylsilyl group. R⁵ is a hydrogen atom or an organic group, and plural R⁵ may be the same or different. The total number of carbon atoms of three R⁵ is 1 or more.

Specific examples of the silylation agent represented by the above formula (2) include hexamethyldisilazane, N-methylhexamethyldisilazane, 1,3-dimethyldisilazane, 1,3-di-n-octyl-1,1,3,3-tetramethyldisilazane, 1,3-divinyl-1,1,3,3-tetramethyldisilazane, tris(dimethylsilyl)amine, tris(trimethylsilyl)amine, 1-ethyl-1,1,3,3,3-pentamethyldisilazane, 1-vinyl-1,1,3,3,3-pentamethyldisilazane, 1-propyl-1,1,3,3,3-pentamethyldisilazane, 1-phenylethyl-1,1,3,3,3-pentamethyldisilazane, 1-tert-butyl-1,1,3,3,3-pentamethyldisilazane, 1-phenyl-1,1,3,3,3-pentamethyldisilazane, and 1,1,1-trimethyl-3,3,3-triethyldisilazane.

### (Silylation Agent Represented by Formula (3))

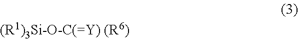

In the above formula (3), R¹ is the same as R¹ in the above formula (1). Y is O, CHR⁷, CHOR⁷, C(R⁷)₂, or NR⁷. R⁷ is a hydrogen atom, a saturated or unsaturated chain hydrocarbon group, a saturated or unsaturated nonaromatic cyclic hydrocarbon group, a trialkylsilyl group, a trialkylsiloxy group, an alkoxy group, a phenyl group, a phenylethyl group, or an acetyl group, and plural R⁷ may be the same or different. R⁶ is a hydrogen atom, an alkyl group, or a trialkylsilyl group.

The saturated or unsaturated chain hydrocarbon group is the same as the saturated or unsaturated chain hydrocarbon group in the organic group in the above formula (1). The saturated or unsaturated nonaromatic cyclic hydrocarbon group is the same as the saturated or unsaturated nonaromatic cyclic hydrocarbon group in the nonaromatic ring group in the above formula (1).

The number of carbon atoms of the alkyl group included in the trialkylsilyl group, the trialkylsiloxy group and the alkoxy group is not particularly limited. The number of carbon atoms of the alkyl group included in these groups is preferably 1 or more and 10 or less, more preferably 1 or more and 8 or less, and still more preferably 1 or more and 3 or less. Suitable examples of the alkyl group included in these groups include a methyl group, an ethyl group, an n-propyl group, an isopropyl group, an n-butyl group, a sec-butyl group, a tert-butyl group, an n-pentyl group, an isopentyl group, a sec-pentyl group, a tert-pentyl group, an n-hexyl group, an n-heptyl group, an n-octyl group, an n-nonyl group, and an n-decyl group. Among these alkyl groups, a methyl group, an ethyl group and an n-propyl group are more preferred, and a methyl group and an ethyl group are still more preferred.

The number of carbon atoms of the alkyl group is not particularly limited. The number of carbon atoms of the alkyl groups is preferably 1 or more and 10 or less, more preferably 1 or more and 8 or less, and still more preferably 1 or more and 3 or less. Suitable examples of the alkyl group include a methyl group, an ethyl group, an n-propyl group, an isopropyl group, an n-butyl group, a sec-butyl group, a tert-butyl group, an n-pentyl group, an isopentyl group, a sec-pentyl group, a tert-pentyl group, an n-hexyl group, an n-heptyl group, an n-octyl group, an n-nonyl group, and an n-decyl group. Among these alkyl groups, a methyl group, an ethyl group, and an n-propyl group are more preferred, and a methyl group and an ethyl group are still more preferred.

Specific examples of the silylation agent represented by the above formula (3) include trimethylsilylacetate, dimethylsilylacetate, monomethylsilylacetate, trimethylsilylpropionate, trimethylsilylbutyrate, and trimethylsilyl-2-butenoate.

### (Silylation Agent Represented by Formula (4))

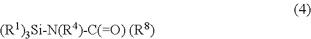

In the above formula (4), R¹ is the same as R¹ in the above formula (1). R⁴ is the same as R⁴ in the above formula (2). R⁸ is a hydrogen atom, a saturated or unsaturated chain hydrocarbon group, a trifluoromethyl group, or a trialkylsilylamino group.

The saturated or unsaturated chain hydrocarbon group is the same as the saturated or unsaturated chain hydrocarbon group in the organic group in the above formula (1).

The alkyl group included in the trialkylsilylamino group are the same as the alkyl group included in the trialkylsilyl group, the trialkylsiloxy group and the alkoxy group in the above formula (3).

Specific examples of the silylation agent represented by the above formula (4) include N,N′-bis(trimethylsilyl) urea, N-trimethylsilylacetamide, N-methyl-N-trimethylsilyltrifluoroacetamide, and N,N-bis(trimethylsilyl)trifluoroacetamide.

### (Silylation Agent Represented by Formula (5))

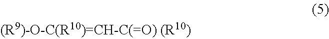

In the above formula (5), R⁹ is a trialkylsilyl group. R¹⁰ is a hydrogen atom or an organic group, and plural R¹⁰ may be the same or different.

The alkyl group included in the trialkylsilyl group is the same as the alkyl group included in the trialkylsilyl group, the trialkylsiloxy group and the alkoxy group in the above formula (3).

The organic group is the same as the organic group in the above formula (1).

Specific examples of the silylation agent represented by the above formula (5) include a 2-trimethylsiloxypentan-2-en-4-one and the like.

### (Silylation Agent Represented by Formula (6))

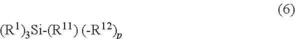

In the above formula (6), R¹ is the same as R¹ in the above formula (1). R¹¹ is a saturated or unsaturated chain hydrocarbon group, a saturated or unsaturated nonaromatic cyclic hydrocarbon group, or a nonaromatic heterocyclic group. p is 0 or 1. When p is 1, R¹² is Si(R¹) 3, and Si in R¹² is bonded to R¹¹. R¹ in R¹² is the same as R¹ in the above formula (1). When p is 0, the saturated or unsaturated chain hydrocarbon group is the same as the saturated or unsaturated chain hydrocarbon group in the organic group in the above formula (1), and the saturated or unsaturated nonaromatic cyclic hydrocarbon group, and the nonaromatic heterocyclic group are the same as the saturated or unsaturated nonaromatic cyclic hydrocarbon group, and the nonaromatic heterocyclic group in the nonaromatic ring group in the above formula (1). When p is 1, the saturated or unsaturated chain hydrocarbon group, the saturated or unsaturated nonaromatic cyclic hydrocarbon group, and the nonaromatic heterocyclic group are divalent groups in which one hydrogen atom is removed from the monovalent groups represented by the saturated or unsaturated chain hydrocarbon group, the saturated or unsaturated nonaromatic cyclic hydrocarbon group, and the nonaromatic heterocyclic group when p is 0.

Specific examples of the silylation agent represented by the above formula (6) include 1,2-bis(dimethylchlorosilyl)ethane and tert-butyldimethylchlorosilane.

### (Silylation Agent Represented by Formula (7))

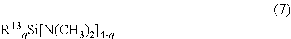

In the above formula (7), R¹³ is a chain hydrocarbon group having 1 or more and 18 or less carbon atoms in which a part or all of hydrogen atoms may be substituted with fluorine atoms, and plural R¹³ may be the same or different. q is 1 or 2.

In R¹³, the number of carbon atoms is preferably 2 or more and 18 or less, and more preferably 8 or more and 18 or less. Examples of the chain hydrocarbon group include a chain saturated hydrocarbon group and a chain unsaturated hydrocarbon group.

Examples of the chain saturated hydrocarbon group not substituted with a fluorine atom include a methyl group, an ethyl group, an n-propyl group, an isopropyl group, a butyl group, a sec-butyl group, a tert-butyl group, an isobutyl group, an amyl group, an isoamyl group, a tert-amyl group, a hexyl group, a 2-hexyl group, a 3-hexyl group, a heptyl group, a 2-heptyl group, a 3-heptyl group, an isoheptyl group, a tert-heptyl group, an n-octyl group, an isooctyl group, a tert-octyl group, a 2-ethylhexyl group, a nonyl group, an isononyl group, a decyl group, a dodecyl group, a tridecyl group, a tetradecyl group, a pentadecyl group, a hexadecyl group, a heptadecyl group, and an octadecyl group.

Examples of the chain unsaturated hydrocarbon group not substituted with a fluorine atom include a vinyl group, a 1-propenyl group, an allyl group, an isopropenyl group, a 1-butenyl group, a 2-butenyl group, a 3-butenyl group, a 1,3-butadienyl group, a 1-ethylvinyl group, a 1-methyl-1-propenyl group, a 1-methyl-2-propenyl group, a 4-pentenyl group, a 1,3-pentadienyl group, a 2,4-pentadienyl group, a 3-methyl-1-butenyl group, a 5-hexenyl group, a 2,4-hexadienyl group, a 6-heptenyl group, a 7-octenyl group, a 8-nonenyl group, a 9-decenyl group, a 10-undecenyl group, a 11-dodecenyl group, a 12-tridecenyl group, a 13-tetradecenyl group, a 14-pentadecenyl group, a 15-hexadecenyl group, a 16-heptadecenyl group, a 17-octadecenyl group, an ethynyl group, a propargyl group, a 1-propynyl group, a 1-butynyl group, a 2-butynyl group, a 3-butynyl group, a 1-pentynyl group, a 2-pentynyl group, a 3-pentynyl group, a 4-pentynyl group, a 1-hexynyl group, a 2-hexynyl group, a 3-hexynyl group, a 4-hexynyl group, a 5-hexynyl group, a 6-heptynyl group, a 7-octynyl group, a 8-nonynyl group, a 9-decynyl group, a 10-undecynyl group, a 11-dodecynyl group, a 12-tridecynyl group, a 13-tetradecynyl group, a 14-pentadecynyl group, a 15-hexadecynyl group, a 16-heptadecynyl group, and a 17-octadecynyl group.

In a chain hydrocarbon group in which a part or all of hydrogen atoms are substituted with fluorine atoms, the number of fluorine atoms substituted and the positions substituted with fluorine atoms are not particularly limited. In a chain hydrocarbon group in which a part of hydrogen atoms are substituted with fluorine atoms, the number of fluorine atoms substituted is preferably 50% or more, more preferably 70% or more, and still more preferably 80% or more, of the number of hydrogen atoms that the chain hydrocarbon group has.

R¹³ is preferably a linear hydrocarbon group having 1 or more and 18 or less carbon atoms in which a part or all of hydrogen atoms may be substituted with fluorine atoms, in terms of easily obtaining excellent effect of hydrophobization. In terms of the storage stability of the silylation agent, R¹³ is more preferably a linear saturated hydrocarbon group having 1 or more and 18 or less carbon atoms in which a part or all of hydrogen atoms may be substituted with fluorine atoms (an alkyl group having 1 or more and 18 or less carbon atoms).

q is 1 or 2, and is preferably 1.

### (Silylation Agent Represented by Formula (8))

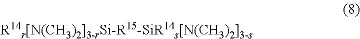

In the above formula (8), R¹⁴ is a hydrogen atom, or a linear or branched alkyl group having 1 or more 4 or less carbon atoms, and plural R¹⁴ may be the same or different. R¹⁵ is a linear or branched alkylene group having 1 or more and 16 or less carbon atoms. r and s each independently represent an integer of 0 or more and 2 or less.

Examples of the linear or branched alkyl group having 1 or more and 4 or less carbon atoms include a methyl group, an ethyl group, an n-propyl group, an isopropyl group, an n-butyl group, a sec-butyl group, a tert-butyl group, and an isobutyl group.

R¹⁴ is preferably a hydrogen atom, or a linear or branched alkyl group having 1 or more and 3 or less carbon atoms, more preferably a hydrogen atom or a methyl group, and still more preferably a methyl group.

The number of carbon atoms of the linear or branched alkylene group is preferably 1 or more and 10 or less, and more preferably 2 or more and 8 or less. The linear alkylene group is a methylene group or an α,ω-linear alkylene group. The branched alkylene group is an alkylene group other than the methylene group and the α,ω-linear alkylene group. R¹⁵ is preferably a linear alkylene group.

Examples of the linear or branched alkylene group having 1 or more and 16 or less carbon atoms include a methylene group, a 1,2-ethylene group, a 1,1-ethylene group, a propane-1,3-diyl group, a propane-1,2-diyl group, a propane-1,1-diyl group, a propane-2,2-diyl group, a butane-1,4-diyl group, a butane-1,3-diyl group, a butane-1,2-diyl group, a butane-1,1-diyl group, a butane-2,2-diyl group, a butane-2,3-diyl group, a pentane-1,5-diyl group, a pentane-1,4-diyl group, a hexane-1,6-diyl group, a heptane-1,7-diyl group, a octane-1,8-diyl group, a 2-ethylhexane-1,6-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, and a hexadecane-1,16-diyl group.

s and r each independently represent an integer of 0 or more and 2 or less. Due to its easy synthesis and availability, s and r are preferably 1 or 2, and more preferably 2.

### (Cyclic Silazane Compound)

Examples of the cyclic silazane compound include cyclic disilazane compounds such as 2,2,5,5-tetramethyl-2,5-disila-1-azacyclopentane and 2,2,6,6-tetramethyl-2,6-disila-1-azacyclohexane; cyclic trisilazane compounds such as 2,2,4,4,6,6-hexamethylcyclotrisilazane and 2,4,6-trimethyl-2,4,6-trivinylcyclotrisilazane; and cyclic tetrasilazane compounds such as 2,2,4,4,6,6,8,8-octamethylcyclotetrasilazane.

Among them, cyclic disilazane compounds are preferred, and 2,2,5,5-tetramethyl-2,5-disila-1-azacyclopentane and 2,2,6,6-tetramethyl-2,6-disila-1-azacyclohexane are more preferred. As the cyclic disilazane compounds, there are those having a five-membered ring structure, such as 2,2,5,5-tetramethyl-2,5-disila-1-azacyclopentane, and those having a six-membered ring structure, such as 2,2,6,6-tetramethyl-2,6-disila-1-azacyclohexane, however, those having a five-membered ring structure are more preferred.

The silylation agents described above may be used alone or in combination of two or more thereof.

A ratio of the mass of the silylation agent to the mass of the surface treatment liquid is 1.000000% by mass or more and 20.000000% by mass or less, preferably 2.000000% by mass or more and 15.000000% by mass or less, and more preferably 3.000000% by mass or more and 13.000000% by mass or less.

### [Solvent]

The solvent includes water and propylene glycol monoalkyl ether acetate, and includes propylene glycol monoalkyl ether and/or propylene glycol monoacetate.

### (Propylene Glycol Monoalkyl Ether Acetate)

The propylene glycol monoalkyl ether acetate has a structure in which the hydrogen atom of a secondary hydroxyl group in propylene glycol is substituted with an acetyl group, and the hydrogen atom of a primary hydroxyl group is substituted with an alkyl group. The alkyl group in the propylene glycol monoalkyl ether acetate is not particularly limited. The alkyl group in the propylene glycol monoalkyl ether acetate is preferably an alkyl group having 1 or more and 4 or less carbon atoms, and more preferably an alkyl group having 1 or 2 carbon atoms. Suitable specific examples of the propylene glycol monoalkyl ether acetate include propylene glycol monomethyl ether acetate and propylene glycol monoethyl ether acetate.

A ratio of the mass of the propylene glycol monoalkyl ether acetate to the mass of the surface treatment liquid is 60.000000% by mass or more and 98.999800% by mass or less, preferably 75.000000% by mass or more and 98.999800% by mass or less, and more preferably 85.000000% by mass or more and 98.999800% by mass or less.

### (Propylene Glycol Monoalkyl Ether)

The propylene glycol monoalkyl ether has a structure in which the hydrogen atom of any one of two hydroxyl groups in propylene glycol is substituted with an alkyl group. The structure of the propylene glycol monoalkyl ether may be either a structure in which the hydrogen atom of a primary hydroxyl group in propylene glycol is substituted with an alkyl group, or a structure in which the hydrogen atom of a secondary hydroxyl group in propylene glycol is substituted with an alkyl group. The propylene glycol monoalkyl ether preferably has a structure in which the hydrogen atom of a primary hydroxyl group in propylene glycol is substituted with an alkyl group. The alkyl group in the propylene glycol monoalkyl ether is not particularly limited. The alkyl group in the propylene glycol monoalkyl ether is preferably an alkyl group having 1 or more and 4 or less carbon atoms, and more preferably an alkyl group having 1 or 2 carbon atoms. Specific examples of the propylene glycol monoalkyl ether include propylene glycol monomethyl ether and propylene glycol monoethyl ether.

### (Propylene Glycol Monoacetate)

The propylene glycol monoacetate has a structure in which the hydrogen atom of any one of two hydroxyl groups in propylene glycol is substituted with an acetyl group. The structure of the propylene glycol monoacetate may be either a structure in which the hydrogen atom of a primary hydroxyl group in propylene glycol is substituted with an acetyl group, or a structure in which the hydrogen atom of a secondary hydroxyl group in propylene glycol is substituted with an acetyl group. The propylene glycol monoacetate preferably has a structure in which the hydrogen atom of a secondary hydroxyl group in propylene glycol is substituted with an acetyl group.

A ratio of the masses/mass of the propylene glycol monoalkyl ether and/or the propylene glycol monoacetate to the mass of the surface treatment liquid is 0.000100% by mass or more and 0.500000% by mass or less.

A ratio of the total mass of the propylene glycol monoalkyl ether and the propylene glycol monoacetate to the mass of the silylation agent is preferably 1.5×10⁻⁵ or more and 6×10⁻² or less.

### (Water)

A ratio of the mass of the water to the mass of the surface treatment liquid is 0.000100% by mass or more and 0.330000% by mass or less, preferably 0.000100% by mass or more and 0.250000% by mass or less, and more preferably 0.000100% by mass or more and 0.180000% by mass or less. A ratio of the mass of the water to the mass of the silylation agent is preferably 5.00×10⁻⁶ or more and 2.0×10⁻² or less.

As long as the desired effect is not impaired, the surface treatment liquid may include other components besides silylation agent, water, propylene glycol monoalkyl ether acetate, propylene glycol monoalkyl ether, and propylene glycol monoacetate. Examples of other components include solvents, surfactants, defoaming agents, and nitrogen-containing heterocyclic compounds containing no silicon atom, other than the water, the propylene glycol monoalkyl ether acetate, the propylene glycol monoalkyl ether, and the propylene glycol monoacetate.

Examples of the solvent other than the water, the propylene glycol monoalkyl ether acetate, the propylene glycol monoalkyl ether, and the propylene glycol monoacetate include aliphatic hydrocarbons having 5 or more and 20 or less carbon atoms, such as n-hexane, n-heptane, n-octane, n-nonane, methyloctane, n-decane, n-undecane, n-dodecane, 2,2,4,6,6-pentamethylheptane, 2,2,4,4,6,8,8-heptamethylnonane, cyclohexane, methylcyclohexane, and bicyclohexyl; dialkyl ethers having 2 or more and 12 or less carbon atoms, such as dimethyl ether, diethyl ether, methyl ethyl ether, di-n-propyl ether, diisopropyl ether, di-n-butyl ether, diisoamyl ether, and di-n-hexyl ether; sulfoxides such as dimethyl sulfoxide; sulfones such as dimethylsulfone, diethylsulfone, bis(2-hydroxyethyl)sulfone, and tetramethylenesulfone; amides such as N,N-dimethylformamide, N-methylformamide, N,N-dimethylacetamide, N-methylacetamide, and N,N-diethylacetamide; lactams such as N-methyl-2-pyrrolidone, N-ethyl-2-pyrrolidone, N-propyl-2-pyrrolidone, N-hydroxymethyl-2-pyrrolidone, and N-hydroxyethyl-2-pyrrolidone; imidazolidinones such as 1,3-dimethyl-2-imidazolidinone, 1,3-diethyl-2-imidazolidinone, and 1,3-diisopropyl-2-imidazolidinone; other ethers such as dimethyl glycol, dimethyl diglycol, dimethyl triglycol, methyl ethyl diglycol, diethyl glycol, diethylene glycol dimethyl ether, diethylene glycol methyl ethyl ether, diethylene glycol diethyl ether, triethylene glycol dimethyl ether, and tetraethylene glycol dimethyl ether; (poly)alkylene glycol monoalkyl ether acetates other than the propylene glycol monoalkyl ether acetate, such as ethylene glycol monomethyl ether acetate, ethylene glycol monoethyl ether acetate, ethylene glycol monobutyl ether acetate, diethylene glycol monomethyl ether acetate, and diethylene glycol monoethyl ether acetate; other esters such as methyl 3-methoxypropionate, ethyl 3-methoxypropionate, methyl 3-ethoxypropionate, ethyl 3-ethoxypropionate, ethyl ethoxyacetate, 3-methoxybutyl acetate, 3-methyl-3-methoxybutyl acetate, 3-methyl-3-methoxybutyl propionate, ethyl acetate, n-propyl acetate, isopropyl acetate, n-butyl acetate, isobutyl acetate, n-pentyl acetate, n-hexyl acetate, n-heptyl acetate, n-octyl acetate, n-pentyl formate, isopentyl acetate, n-butyl propionate, ethyl butyrate, n-propyl butyrate, isopropyl butyrate, n-butyl butyrate, methyl n-octanoate, methyl decanoate, methyl pyruvate, ethyl pyruvate, n-propyl pyruvate, methyl acetoacetate, ethyl acetoacetate, ethyl 2-oxobutanoate, dimethyl adipate, and propylene glycol diacetate; ketones such as methyl ethyl ketone, cyclohexanone, 2-heptanone, and 3-heptanone; lactones such as β-propiolactone, γ-butyrolactone, and δ-pentylolactone; aromatic hydrocarbons such as benzene, toluene, xylene, 1,3,5-trimethylbenzene, and naphthalene; and terpenes such as p-menthane, diphenylmenthane, limonene, terpinene, bornane, norbornane, and pinane.

The nitrogen-containing heterocyclic compound containing no silicon atom (hereinafter simply referred to as “nitrogen-containing heterocyclic compound”) promotes the silylation reaction caused by the silylation agent. When a surface treatment liquid containing a nitrogen-containing heterocyclic compound is used, the surface treatment time of a substrate can be further shortened.

The nitrogen-containing heterocyclic compound is not particularly limited as long as it is a compound which does not include a silicon atom and includes a nitrogen atom in the ring structure. The nitrogen-containing heterocyclic compound may include heteroatoms other than the nitrogen atom, such as an oxygen atom and a sulfur atom, in the ring structure. In terms of further enhancing the hydrophobicity of the surface of the surface-treated substrate, the nitrogen-containing heterocyclic compound is preferably a compound including a nitrogen-containing heterocycle having aromaticity.

The nitrogen-containing heterocyclic compound may be a compound in which two or more rings are linked by a single bond or a divalent or higher polyvalent linking group. In this case, two or more rings linked by the linking group may include at least one nitrogen-containing heterocycle. Among polyvalent linking groups, divalent linking groups are preferred in terms of small steric hindrance between the rings. Specific examples of the divalent linking group include an alkylene group having 1 or more and 6 or less carbon atoms, —CO—, —CS—, —O—, —S—, —NH—, —N═N—, —CO—O—, —CO—NH—, —CO—S—, —CS—O—, —CS—S—, —CO—NH—CO—, —NH—CO—NH—, —SO—, —SO₂— and the like. The number of rings included in a compound in which two or more rings are linked by a polyvalent linking group is preferably 4 or less, more preferably 3 or less, and most preferably 2, in terms of easily preparing a uniform surface treatment liquid. Note that for a condensed ring such as a naphthalene ring, the number of rings is set at two.

The nitrogen-containing heterocyclic compound may be a compound in which plural rings are fused. In this case, at least one of the rings constituting the fused ring may be a nitrogen-containing heterocycle. The number of rings included in the nitrogen-containing heterocyclic compound in which plural rings are fused is preferably 4 or less, more preferably 3 or less, and still more preferably 2, in terms of easily preparing a uniform surface treatment liquid.

In terms of satisfactory effect of a surface treatment using the surface treatment liquid, the nitrogen-containing heterocyclic compound preferably includes a nitrogen-containing five-membered ring or a fused polycyclic ring including a nitrogen-containing five-membered ring skeleton.

Suitable examples of the nitrogen-containing heterocyclic compound include pyridine, pyridazine, pyrazine, pyrimidine, triazine, tetrazine, pyrrole, pyrazole, imidazole, triazole, tetrazole, oxazole, isooxazole, thiazole, isothiazole, oxadiazole, thiadiazole, quinoline, isoquinoline, cinnoline, phthalazine, quinoxaline, quinazoline, indole, indazole, benzoimidazole, benzotriazole, benzoxazole, benzisoxazole, benzothiazole, benzisothiazole, benzoxadiazole, benzothiadiazole, saccharin, pyrrolidine, and piperidine. Among them, pyrrole, pyrazole, imidazole, triazole, tetrazole, oxazole, isooxazole, thiazole, isothiazole, oxadiazole, thiadiazole, indole, indazole, benzoimidazole, benzotriazole, benzoxazole, benzisoxazole, benzothiazole, benzisothiazole, benzoxadiazole, benzothiadiazole, and saccharin are preferred, and imidazole, triazole, tetrazole, benzotriazole and pyrazole are more preferred. The above nitrogen-containing heterocyclic compounds having a substituent are also preferably used.

Examples of the substituent that the nitrogen-containing heterocyclic compound may have include an alkyl group having 1 or more and 6 or less carbon atoms, a cycloalkyl group having 3 or more and 8 or less carbon atoms, an alkoxy group having 1 or more and 6 or less carbon atoms, a cycloalkyloxy group having 3 or more and 8 or less carbon atoms, an aryl group having 6 or more and 20 or less carbon atoms, an aralkyl group having 7 or more and 20 or less carbon atoms, an alkyl halide group having 1 or more and 6 or less carbon atoms, an aliphatic acyl group having 2 or more and 7 or less carbon atoms, a haloaliphatic acyl group having 2 or more and 7 or less carbon atoms, an arylcarbonyl group having 7 or more and 20 or less carbon atoms, a carboxyalkyl group having 2 or more and 7 or less carbon atoms, a halogen atom, a mercapto group, an alkylthio group having 1 or more and 6 or less carbon atoms, an amino group, a monoalkylamino group which has an alkyl group having 1 or more and 6 or less carbon atoms, an dialkylamino group which has an alkyl group having 1 or more and 6 or less carbon atoms, a nitro group, and a cyano group. The nitrogen-containing heterocyclic compound may have plural substituents on the nitrogen-containing heterocycle. When there are plural substituents, plural substituents may be the same or different. When these substituents include an aliphatic hydrocarbon ring, an aromatic hydrocarbon ring and the like, these rings may further have the same substituents as those that the nitrogen-containing heterocyclic compound may have.

The number of carbon atoms of the alkyl group as the substituent is 1 or more and 6 or less, preferably 1 or more and 4 or less, and still more preferably 1 or 2. Specific examples of the alkyl group having 1 or more and 6 or less carbon atoms include a methyl group, an ethyl group, an n-propyl group, an isopropyl group, an n-butyl group, an isobutyl group, a sec-butyl group, a tert-butyl group, an n-pentyl group, and an n-hexyl group. Among them, a methyl group and an ethyl group are preferred, and a methyl group is more preferred.

The number of carbon atoms of the cycloalkyl group as the substituent is 3 or more and 8 or less, preferably 3 or more and 7 or less, and more preferably 4 or more and 6 or less. Specific examples of the cycloalkyl group having 3 or more and 8 or less carbon atoms include a cyclopropyl group, a cyclobutyl group, a cyclopentyl group, a cyclohexyl group, a cycloheptyl group, and a cyclooctyl group.

The number of carbon atoms of the alkoxy group as the substituent is 1 or more 6 or less, preferably 1 or more and 4 or less, and more preferably 1 or 2. Specific examples of the alkoxy group having 1 or more and 6 or less carbon atoms include a methoxy group, an ethoxy group, an n-propyloxy group, an isopropyloxy group, an n-butyloxy group, an isobutyloxy group, a sec-butyloxy group, a tert-butyloxy group, an n-pentyloxy group, and an n-hexyloxy group. Among them, a methoxy group and an ethoxy group are preferred, and a methoxy group is more preferred.

The number of carbon atoms of the cycloalkyloxy group as the substituent is 3 or more and 8 or less, preferably 3 or more and 7 or less, and more preferably 4 or more and 6 or less. Specific examples of the cycloalkyloxy group having 3 or more and 8 or less carbon atoms include a cyclopropyloxy group, a cyclobutyloxy group, a cyclopentyloxy group, a cyclohexyloxy group, a cycloheptyloxy group, and a cyclooctyloxy group.

The number of carbon atoms of the aryl group as the substituent is 6 or more and 20 or less, and preferably 6 or more and 12 or less. Specific examples of the aryl group having 6 or more and 20 or less carbon atoms include a phenyl group, an α-naphthyl group, a β-naphthyl group, a biphenyl-4-yl group, a biphenyl-3-yl group, a biphenyl-2-yl group, an anthracen-1-yl group, an anthracen-2-yl group, an anthracen-9-yl group, a phenanthren-1-yl group, a phenanthren-2-yl group, a phenanthren-3-yl group, a phenanthren-4-yl group, and a phenanthren-9-yl group. Among them, a phenyl group, an α-naphthyl group, a β-naphthyl group, a biphenyl-4-yl group, a biphenyl-3-yl group, and a biphenyl-2-yl group are preferred, and a phenyl group is more preferred.

The number of carbon atoms of aralkyl groups as the substituent is 7 or more and 20 or less, and preferably 7 or more and 12 or less. Specific examples of the aralkyl group having 7 or more and 20 or less carbon atoms include a benzyl group, a phenethyl group, a 3-phenyl-n-propyl group, a 4-phenyl-n-butyl group, an α-naphthylmethyl group, a β-naphthylmethyl group, a 2-(α-naphthyl)ethyl group, and a 2-(β-naphthyl)ethyl group. Among these groups, a benzyl group and a phenethyl group are preferred, and a benzyl group is more preferred.

Examples of the halogen atom as the substituent included in the alkyl halide group include a fluorine atom, a chlorine atom, a bromine atom, and an iodine atom. The number of carbon atoms of the alkyl halide group as the substituent is 1 or more and 6 or less, preferably 1 or more and 4 or less, and more preferably 1 or 2. Specific examples of the alkyl halide group having 1 or more and 6 or less carbon atoms include a chloromethyl group, a dichloromethyl group, a trichloromethyl group, a fluoromethyl group, a difluoromethyl group, a trifluoromethyl group, a 1,1-difluoroethyl group, a 2,2,2-trifluoroethyl group, and a pentafluoroethyl group.

The number of carbon atoms of the aliphatic acyl group as the substituent is 2 or more and 7 or less, preferably 2 or more and 5 or less, and more preferably 2 or 3. Specific examples of the aliphatic acyl group having 2 or more and 7 or less carbon atoms include an acetyl group, a propionyl group, a butanoyl group, a pentanoyl group, a hexanoyl group, and a heptanoyl group. Among them, an acetyl group and a propanoyl group are preferred, and an acetyl group is more preferred.

Examples of the halogen atom as the substituent included in the haloaliphatic acyl group include a fluorine atom, a chlorine atom, a bromine atom, and an iodine atom. The number of carbon atoms of the haloaliphatic acyl group as the substituent is 2 or more 7 or less, preferably 2 or more and 5 or less, and more preferably 1 or 2. Specific examples of the haloaliphatic acyl group having 2 or more and 7 or less carbon atoms include a chloroacetyl group, a dichloroacetyl group, a trichloroacetyl group, a fluoroacetyl group, a difluoroacetyl group, a trifluoroacetyl group, and a pentafluoropropionyl group.

The number of carbon atoms of the arylcarbonyl group as the substituent is 7 or more and 20 or less, and preferably 7 or more and 13 or less. Specific examples of the arylcarbonyl group having 7 or more and 20 or less carbon atoms include a benzoyl group, an α-naphthoyl group, and a β-naphthoyl group.

The number of carbon atoms of the carboxyalkyl group as the substituent is 2 or more and 7 or less, preferably 2 or more and 5 or less, and more preferably 2 or 3. Specific examples of the carboxyalkyl group having 2 or more and 7 or less carbon atoms include a carboxymethyl group, a 2-carboxyethyl group, a 3-carboxy-n-propyl group, a 4-carboxy-n-butyl group, a 5-carboxy-n-pentyl group, and a 6-carboxy-n-hexyl group. Among them, a carboxymethyl group is preferred.

Examples of the halogen atom include a fluorine atom, a chlorine atom, a bromine atom, and an iodine atom. Among them, a fluorine atom, a chlorine atom, and a bromine atom are preferred, and a chlorine atom and a bromine atom are more preferred.

The number of carbon atoms of the alkylthio group as the substituent is 1 or more and 6 or less, preferably 1 or more and 4 or less, and more preferably 1 or 2. Specific examples of the alkylthio group having 1 or more and 6 or less carbon atoms include a methylthio group, an ethylthio group, an n-propylthio group, an isopropylthio group, an n-butylthio group, an isobutylthio group, a sec-butylthio group, a tert-butylthio group, an n-pentylthio group, and an n-hexylthio group. Among them, a methylthio group and an ethylthio group are preferred, and a methylthio group is more preferred.

Specific examples of the alkyl group included in the monoalkylamino group which has an alkyl group having 1 or more and 6 or less carbon atoms, and the dialkylamino group which has an alkyl group having 1 or more and 6 or less carbon atoms are the same as the specific examples of the alkyl group as the above substituent. As the monoalkylamino group which has an alkyl group having 1 or more and 6 or less carbon atoms, an ethylamino group and a methylamino group are preferred, and a methylamino group is more preferred. As the dialkylamino group which has an alkyl group having 1 or more and 6 or less carbon atoms, a diethylamino group and a dimethylamino group are preferred, and a dimethylamino group is more preferred.

Particularly preferred specific examples of the nitrogen-containing heterocyclic compound include compounds of the following formulas.

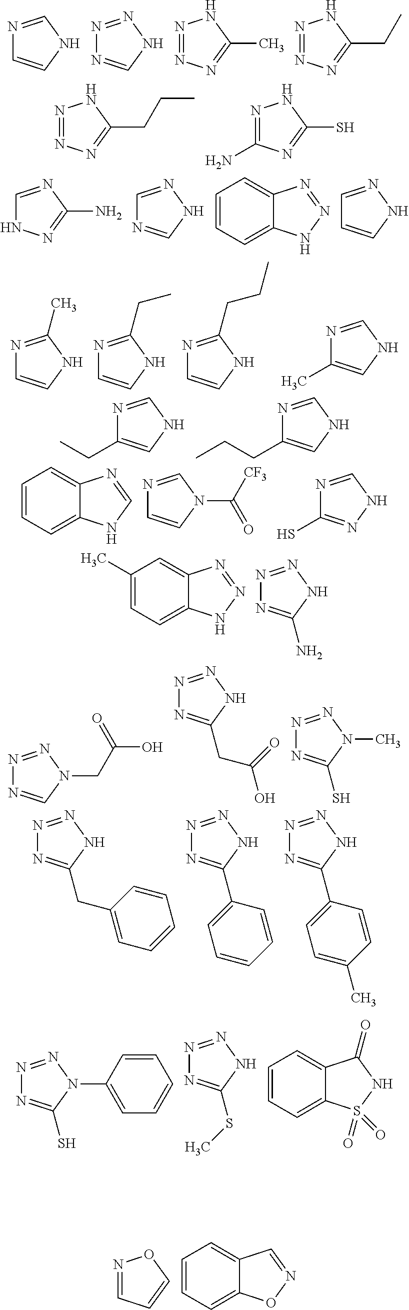

### <Surface Treatment Method>

The surface treatment method is a method including bringing a surface treatment liquid into contact with a surface of a substrate to treat the surface of the substrate. According to such surface treatment method, it is possible to hydrophobize (silylate) the surface of the substrate. Note that the surface treatment liquid and the substrate are as mentioned above.

There is no particular limitation on the method for bringing a surface treatment liquid into contact with a surface of a substrate. Examples of the method for bringing a surface treatment liquid into contact with a surface of a substrate include a spraying method, a spin coating method, an immersion method, a roll coating method, and a doctor blade method. There is no particular limitation on the time during which a surface treatment liquid is brought into contact with a surface of a substrate as long as the desired effect is obtained. Examples of the surface treatment time include 1 second or more and 60 seconds or less.

After the surface treatment liquid is brought into contact with the surface of the substrate, if a solvent or the like derived from the surface treatment liquid remains on the surface of the substrate, it is preferred to remove such residue. The method for removing the residue is not particularly limited. Examples of the method for removing the residue include a method in which the substrate after contact with the surface treatment liquid is immersed in a solvent or the like which is easy to remove, and then a gas such as nitrogen or dry air is blown over the surface of the substrate, a method in which the substrate is heated to an appropriate temperature depending on the boiling point of the solvent to be removed and the like.

As mentioned above, the present inventors provide the following (1) to (5).
(1) A surface treatment liquid used for a hydrophobization treatment of a substrate, wherein
the surface treatment liquid includes a silylation agent and a solvent,
the solvent includes water and propylene glycol monoalkyl ether acetate, and includes propylene glycol monoalkyl ether and/or propylene glycol monoacetate,
a ratio of the mass of the silylation agent to the mass of the surface treatment liquid is 1.000000% by mass or more and 20.000000% by mass or less,
a ratio of the mass of the propylene glycol monoalkyl ether acetate to the mass of the surface treatment liquid is 60.000000% by mass or more and 98.999800% by mass or less,
a ratio of the masses/mass of the propylene glycol monoalkyl ether and/or the propylene glycol monoacetate to the mass of the surface treatment liquid is 0.000100% by mass or more and 0.500000% by mass or less, and
a ratio of the mass of the water to the mass of the surface treatment liquid is 0.000100% by mass or more and 0.330000% by mass or less.
(2) The surface treatment liquid according to (1), wherein a ratio of the total mass of the propylene glycol monoalkyl ether and the propylene glycol monoacetate to the mass of the silylation agent is 1.5×10⁻⁵ or more and 6×10⁻² or less.
(3) The surface treatment liquid according to (1) or (2), wherein a ratio of the mass of the water to the mass of the silylation agent is 5.00×10⁻⁶ or more and 2.0×10⁻² or less.
(4) The surface treatment liquid according to any one of (1) to (3), wherein the silylation agent includes a compound represented by the following formula (1):

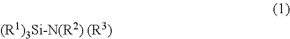

wherein, in formula (1), R¹ is a hydrogen atom, a halogen atom or an organic group, plural R¹ may be the same or different, the total number of carbon atoms in three R¹ is 1 or more, R² is a hydrogen atom or a chain hydrocarbon group, R³ is a hydrogen atom, a chain hydrocarbon group or a nonaromatic ring group, and R² and R³ may be bonded to each other to form a ring.
(5) A surface treatment method including bringing the surface treatment liquid according to any one of (1) to (4) into contact with a surface of a substrate to treat the surface of the substrate.

### Examples

The present invention will be described in more detail below by way of Examples. Note that the present invention is not limited to the following Examples.

### Examples 1 to 19, and Comparative Examples 1 to 31

### <Preparation of Surface Treatment Liquid>

TMSDMA, TMDS, PGMEA, PGME, PGMA, and water were uniformly mixed such that they have the contents (% by mass) shown in Tables 1 to 9, respectively, to obtain surface treatment liquids of Examples and Comparative Examples.

The components used in Examples and Comparative Examples are as follows.

### (Silylation Agent)

TMSDMA: N,N-dimethylaminotrimethylsilane
TMDS: 1,1,3,3-tetramethyldisilazane

### (Solvent)

PGMEA: propylene glycol monomethyl ether acetate
PGME: propylene glycol monomethyl ether
PGMA: propylene glycol-1-acetate

### Water

Tables 1 to 9 show ratios of the masses of PGME and PGMA to the mass of the silylation agent, and a ratio of the mass of water to the mass of the silylation agent, for each surface treatment agent in Examples and Comparative Examples.

### <Surface Treatment of Silicon Substrate>

A silicon substrate without a pattern on its surface was immersed in hydrofluoric acid (aqueous 49% by weight hydrofluoric acid solution:water=1:100 (volume ratio)) for 1 minute, and then washed with water. The silicon substrate after cleaning with water was dried by nitrogen flow. The dried silicon substrate was immersed in SC1 for 1 minute, and then the silicon substrate removed from SC1 was cleaned with water for 1 minute. SC1 is a solution in which a 318 by mass concentration of hydrogen peroxide water, a 29% by mass concentration of ammonia water, and water were mixed in a ratio of 1:1:5 (volume ratio) of hydrogen peroxide water:ammonia water:water. The silicon substrate cleaned with water was dried by nitrogen flow. Each of the above operations was performed at room temperature.

The dried silicon substrate was immersed in a surface treatment liquid for 20 seconds to perform a surface treatment of the silicon substrate. The surface-treated silicon substrate was then cleaned with isopropyl alcohol for 1 minute. The cleaned silicon substrate was then dried by nitrogen flow.

### <Measurement of Contact Angle of Water>

A contact angle was measured using Dropmaster 700 (manufactured by Kyowa Interface Science Co., Ltd.). Specifically, a droplet of pure water (2.0 μL) was dropped onto the surface of the surface-treated substrate after drying, and the contact angle was measured 1.0 second after the drop. The measurement results of the contact angle are shown in Tables 1 to 9. When the contact angle was 80 degrees or more, it was determined that the surface of the silicon substrate was satisfactorily hydrophobized. Note that the contact angle was similarly measured for each substrate before the surface treatment, and the results were all 10.0 degrees or less.

TABLE 1

| | | | Example | | | | | Comparative |
|---|---|---|---|---|---|---|---|---|
| | | | 1 | 2 | 3 | 4 | 5 | Example 1 |
| Surface | Silylation agent | TMSDMA | 7.800000 | 7.800000 | 7.800000 | 7.800000 | 7.800000 | 7.800000 |
| treatment | (% by mass) | | | | | | | |
| liquid | Solvent | PGME | 0.000164 | 0.000329 | 0.000329 | 0.000329 | — | 0.0000164 |
| | (% by mass) | PGMA | — | — | — | — | 0.000329 | — |
| | | PGMEA | 92.199736 | 92.199571 | 92.147855 | 92.067762 | 92.147855 | 92.1998836 |
| | | Water | 0.000100 | 0.000100 | 0.051816 | 0.131909 | 0.051816 | 0.000100 |

| | | | | | | |
|---|---|---|---|---|---|---|
| Total (% by mass) | 100.000000 | 100.000000 | 100.000000 | 100.000000 | 100.000000 | 100.000000 |

| | | | | | | |
|---|---|---|---|---|---|---|
| Ratio of masses of PGME and PGMA | 2.10 × | 4.22 × | 4.22 × | 4.22 × | 4.22 × | 2.11 × |
| to mass of silylation agent | 10⁻⁵ | 10⁻⁵ | 10⁻⁵ | 10⁻⁵ | 10⁻⁵ | 10⁻⁶ |
| Ratio of mass of water to mass of | 1.28 × | 1.28 × | 6.64 × | 1.69 × | 6.64 × | 1.28 × |
| silylation agent | 10⁻⁵ | 10⁻⁵ | 10⁻³ | 10⁻² | 10⁻³ | 10⁻⁵ |
| Contact angle (degree) on | 85.2 | 85.2 | 88.9 | 81.9 | 86.2 | 77.5 |
| substrate after surface treatment | | | | | | |

TABLE 2

| | | | Example | | | | | Comparative |
|---|---|---|---|---|---|---|---|---|
| | | | 6 | 7 | 8 | 9 | 10 | Example 2 |
| Surface | Silylation agent | TMSDMA | 7.800000 | 7.800000 | 7.800000 | 7.800000 | 7.800000 | 7.800000 |
| treatment | (% by mass) | | | | | | | |
| liquid | Solvent | PGME | 0.001645 | 0.003285 | 0.003288 | 0.003290 | 0.003290 | 1.977690 |
| | (% by mass) | PGMEA | 92.198255 | 92.064806 | 92.144896 | 92.196610 | 92.195710 | 90.222210 |
| | | Water | 0.000100 | 0.131909 | 0.051816 | 0.000100 | 0.001000 | 0.000100 |

| | | | | | | |
|---|---|---|---|---|---|---|
| Total (% by mass) | 100.000000 | 100.000000 | 100.000000 | 100.000000 | 100.000000 | 100.000000 |

| | | | | | | |
|---|---|---|---|---|---|---|
| Ratio of mass of PGME to mass of | 2.11 × | 4.21 × | 4.22 × | 4.22 × | 4.22 × | 2.54 × |
| silylation agent | 10⁻⁴ | 10⁻⁴ | 10⁻⁴ | 10⁻⁴ | 10⁻⁴ | 10⁻¹ |
| Ratio of mass of water to mass of | 1.28 × | 1.69 × | 6.64 × | 1.28 × | 1.28 × | 1.28 × |
| silylation agent | 10⁻⁵ | 10⁻² | 10⁻³ | 10⁻⁵ | 10⁻⁴ | 10⁻⁵ |
| Contact angle (degree) on | 89.8 | 82.1 | 87.4 | 83.5 | 87.5 | 77.5 |
| substrate after surface treatment | | | | | | |

TABLE 3

| | | | Example | | | | | |
|---|---|---|---|---|---|---|---|---|
| | | | 11 | 12 | 13 | 14 | 15 | 16 |
| Surface | Silylation agent | TMSDMA | 7.800000 | 7.800000 | 7.800000 | 7.800000 | 7.800000 | 7.800000 |
| treatment | (% by mass) | | | | | | | |
| liquid | Solvent | PGME | 0.009888 | 0.009888 | 0.098885 | 0.098885 | 0.197769 | 0.395538 |
| | (% by mass) | PGMEA | 92.190012 | 92.138295 | 92.101016 | 92.049299 | 92.002131 | 91.804362 |
| | | Water | 0.000100 | 0.051816 | 0.000100 | 0.051816 | 0.000100 | 0.000100 |

| | | | | | | |
|---|---|---|---|---|---|---|
| Total (% by mass) | 100.000000 | 100.000000 | 100.000000 | 100.000000 | 100.000000 | 100.000000 |

| | | | | | | |
|---|---|---|---|---|---|---|
| Ratio of mass of PGME to mass of | 1.27 × | 1.27 × | 1.27 × | 1.27 × | 2.54 × | 5.07 × |
| silylation agent | 10⁻³ | 10⁻³ | 10⁻² | 10⁻² | 10⁻² | 10⁻² |
| Ratio of mass of water to mass of | 1.28 × | 6.64 × | 1.28 × | 6.64 × | 1.28 × | 1.28 × |
| silylation agent | 10⁻⁵ | 10⁻³ | 10⁻⁵ | 10⁻³ | 10⁻⁵ | 10⁻⁵ |
| Contact angle (degree) on | 84.5 | 82.4 | 80.6 | 80.1 | 80.2 | 80.9 |
| substrate after surface treatment | | | | | | |

TABLE 4

| | | | Example | | | Comparative Example | | |
|---|---|---|---|---|---|---|---|---|
| | | | 17 | 18 | 19 | 3 | 4 | 5 |
| Surface | Silylation agent | TMSDMA | 3.900000 | 6.800000 | 11.700000 | 7.800000 | 7.800000 | 7.800000 |
| treatment | (% by mass) | | | | | | | |
| liquid | Solvent | PGME | 0.003290 | 0.003290 | 0.003290 | 3.955380 | 11.866140 | 11.866140 |
| | (% by mass) | PGMEA | 96.096610 | 93.196610 | 88.296610 | 88.244520 | 80.333760 | 77.567860 |
| | | Water | 0.000100 | 0.000100 | 0.000100 | 0.000100 | 0.000100 | 2.766000 |

| | | | | | | |
|---|---|---|---|---|---|---|
| Total (% by mass) | 100.000000 | 100.000000 | 100.000000 | 100.000000 | 100.000000 | 100.000000 |

| | | | | | | |
|---|---|---|---|---|---|---|
| Ratio of mass of PGME to mass of | 8.44 × | 4.84 × | 2.81 × | 5.07 × | 1.52 | 1.52 |
| silylation agent | 10⁻⁴ | 10⁻⁴ | 10⁻⁴ | 10−1 | | |
| Ratio of mass of water to mass of | 2.56 × | 1.47 × | 8.55 × | 1.28 × | 1.28 × | 3.55 × |
| silylation agent | 10⁻⁵ | 10⁻⁵ | 10⁻⁶ | 10⁻⁵ | 10⁻⁵ | 10⁻¹ |
| Contact angle (degree) on | 81.5 | 84.2 | 86.9 | 75.7 | 53.2 | 6.5 |
| substrate after surface treatment | | | | | | |

TABLE 5

| | | | Comparative Example | | | | |
|---|---|---|---|---|---|---|---|
| | | | 6 | 7 | 8 | 9 | 10 |
| Surface | Silylation agent | TMSDMA | 7.800000 | 7.800000 | 7.800000 | 7.800000 | 7.800000 |
| treatment | (% by mass) | | | | | | |
| liquid | Solvent | PGME | 19.776900 | 0.003278 | 0.003272 | 0.003257 | 0.003191 |
| | (% by mass) | PGMEA | 72.423000 | 91.862477 | 91.697827 | 91.274743 | 89.430809 |
| | | Water | 0.000100 | 0.334246 | 0.498901 | 0.922000 | 2.766000 |

| | | | | | |
|---|---|---|---|---|---|
| Total (% by mass) | 100.000000 | 100.000000 | 100.000000 | 100.000000 | 100.000000 |

| | | | | | |
|---|---|---|---|---|---|
| Ratio of mass of PGME to mass of | 2.54 | 4.20 × | 4.19 × | 4.18 × | 4.09 × |
| silylation agent | | 10⁻⁴ | 10⁻⁴ | 10⁻⁴ | 10⁻⁴ |
| Ratio of mass of water to mass of | 1.28 × | 4.29 × | 6.40 × | 1.18 × | 3.55 × |
| silylation agent | 10⁻⁵ | 10⁻² | 10⁻² | 10⁻¹ | 10⁻¹ |
| Contact angle (degree) on substrate | 7.0 | 78.9 | 77.0 | 52.2 | <10 |
| after surface treatment | | | | | |

TABLE 6

| | | | Comparative Example | | | | | |
|---|---|---|---|---|---|---|---|---|
| | | | 11 | 12 | 13 | 14 | 15 | 16 |
| Surface | Silylation agent | TMDS | 7.800000 | 7.800000 | 7.800000 | 7.800000 | 7.800000 | 7.800000 |
| treatment | (% by mass) | | | | | | | |
| liquid | Solvent | PGME | 0.000329 | 0.000329 | 0.01645 | 0.0000164 | 0.003290 | 1.977690 |
| | (% by mass) | PGMEA | 92.147855 | 92.067762 | 92.198255 | 92.1998836 | 92.196610 | 90.222210 |
| | | Water | 0.051816 | 0.131909 | 0.000100 | 0.000100 | 0.000100 | 0.000100 |

| | | | | | | |
|---|---|---|---|---|---|---|
| Total (% by mass) | 100.000000 | 100.000000 | 100.000000 | 100.000000 | 100.000000 | 100.000000 |

| | | | | | | |
|---|---|---|---|---|---|---|
| Ratio of masses of PGME to mass of | 4.22 × | 4.22 × | 2.11 × | 2.11 × | 4.22 × | 2.54 × |
| silylation agent | 10⁻⁵ | 10⁻⁵ | 10⁻⁴ | 10⁻⁶ | 10⁻⁴ | 10⁻¹ |
| Ratio of mass of water to mass of | 6.64 × | 1.69 × | 1.28 × | 1.28 × | 1.28 × | 1.28 × |
| silylation agent | 10⁻³ | 10⁻² | 10⁻⁵ | 10⁻⁵ | 10⁻⁵ | 10⁻⁵ |
| Contact angle (degree) on substrate | 46.9 | 52.7 | 43.4 | 74.3 | 49.1 | 48.4 |
| after surface treatment | | | | | | |

TABLE 7

| | | | Comparative Example | | | | | |
|---|---|---|---|---|---|---|---|---|
| | | | 17 | 18 | 19 | 20 | 21 | 22 |
| Surface | Silylation agent | TMDS | 7.800000 | 7.800000 | 7.800000 | 7.800000 | 7.800000 | 7.800000 |
| treatment | (% by mass) | | | | | | | |
| liquid | Solvent | PGME | 0.009888 | 0.009888 | 0.098885 | 0.098885 | 0.197769 | 0.395538 |
| | (% by mass) | PGMEA | 92.190012 | 92.138295 | 92.101016 | 92.049299 | 92.002131 | 91.804362 |
| | | Water | 0.000100 | 0.051816 | 0.000100 | 0.051816 | 0.000100 | 0.000100 |

| | | | | | | |
|---|---|---|---|---|---|---|
| Total (% by mass) | 100.000000 | 100.000000 | 100.000000 | 100.000000 | 100.000000 | 100.000000 |

| | | | | | | |
|---|---|---|---|---|---|---|
| Ratio of mass of PGME to mass of | 1.27 × | 1.27 × | 1.27 × | 1.27 × | 2.54 × | 5.07 × |
| silylation agent | 10⁻³ | 10⁻³ | 10⁻² | 10⁻² | 10⁻² | 10⁻² |
| Ratio of mass of water to mass of | 1.28 × | 6.64 × | 1.28 × | 6.64 × | 1.28 × | 1.28 × |
| silylation agent | 10⁻⁵ | 10⁻³ | 10⁻⁵ | 10⁻³ | 10⁻⁵ | 10⁻⁵ |
| Contact angle (degree) on substrate | 48.3 | 53.3 | 48.6 | 42.7 | 46.1 | 45.5 |
| after surface treatment | | | | | | |

TABLE 8

| | | | Comparative Example | | | | | |
|---|---|---|---|---|---|---|---|---|
| | | | 23 | 24 | 25 | 26 | 27 | 28 |
| Surface | Silylation agent | TMDS | 7.800000 | 7.800000 | 7.800000 | 7.800000 | — | 7.800000 |
| treatment | (% by mass) | TMSDMA | — | — | — | — | 7.800000 | — |
| liquid | Solvent | PGME | 3.955380 | 11.866140 | 11.866140 | 19.776900 | 0.003290 | 0.003290 |
| | (% by mass) | PGMEA | 88.244520 | 80.333760 | 77.567860 | 72.423000 | 92.1966737 | 92.1966737 |
| | | Water | 0.000100 | 0.000100 | 2.766000 | 0.000100 | 0.0000366 | 0.0000366 |

| | | | | | | |
|---|---|---|---|---|---|---|
| Total (% by mass) | 100.000000 | 100.000000 | 100.000000 | 100.000000 | 100.000000 | 100.000000 |

| | | | | | | |
|---|---|---|---|---|---|---|
| Ratio of mass of PGME to mass of | 5.07 × | 1.52 | 1.52 | 2.54 | 4.22 × | 4.22 × |
| silylation agent | 10⁻¹ | | | | 10⁻⁴ | 10⁻⁴ |
| Ratio of mass of water to mass of | 1.28 × | 1.28 × | 3.55 × | 1.28 × | 4.69 × | 4.69 × |
| silylation agent | 10⁻⁵ | 10⁻⁵ | 10⁻¹ | 10⁻⁵ | 10⁻⁶ | 10⁻⁶ |
| Contact angle (degree) on substrate | 49.4 | 47.1 | 40.9 | 48.9 | 77.6 | 48.5 |
| after surface treatment | | | | | | |

TABLE 9

| | | | Comparative Example | | |
|---|---|---|---|---|---|
| | | | 29 | 30 | 31 |
| Surface | Silylation agent (% by mass) | TMDS | 3.900000 | 6.800000 | 11.700000 |
| treatment | Solvent (% by mass) | PGME | 0.003290 | 0.003290 | 0.003290 |
| liquid | | PGMEA | 96.096610 | 93.196610 | 88.296610 |
| | | Water | 0.000100 | 0.000100 | 0.000100 |

| | | | |
|---|---|---|---|
| Total (% by mass) | 100.000000 | 100.000000 | 100.000000 |

| | | | |
|---|---|---|---|
| Ratio of mass of PGME to mass of silylation agent | 8.44 × 10⁻⁴ | 4.84 × 10⁻⁴ | 2.81 × 10⁻⁴ |
| Ratio of mass of water to mass of silylation agent | 2.56 × 10⁻⁵ | 1.47 × 10⁻⁵ | 8.55 × 10⁻⁶ |
| Contact angle (degree) on substrate after surface treatment | 40.4 | 41.7 | 45.6 |

Tables 1 to 9 show that show that when a silicon substrate is surface-treated using the surface treatment liquids of Examples each including a silylation agent and a solvent and including, as the solvent, water, propylene glycol monomethyl ether acetate and propylene glycol monomethyl ether, in which the contents of the silylation agent (TMSDMA), the propylene glycol monomethyl ether acetate, the propylene glycol monomethyl ether and water are respectively within the above-mentioned predetermined ranges relative to the mass of the surface treatment liquid, the surface of the silicon substrate is satisfactorily hydrophobized.

What is claimed is:

1. A surface treatment liquid for use for a hydrophobization treatment of a substrate,
the surface treatment liquid comprising a silylation agent and a solvent,
the solvent comprising water and propylene glycol monoalkyl ether acetate, and comprising propylene glycol monoalkyl ether and/or propylene glycol monoacetate,
a ratio of a mass of the silylation agent to a mass of the surface treatment liquid being 1.000000% by mass or more and 20.000000% by mass or less,
a ratio of a mass of the propylene glycol monoalkyl ether acetate to the mass of the surface treatment liquid being 60.000000% by mass or more and 98.999800% by mass or less,
a ratio of masses/mass of the propylene glycol monoalkyl ether and/or the propylene glycol monoacetate to the mass of the surface treatment liquid being 0.000100% by mass or more and 0.500000% by mass or less, and
a ratio of a mass of the water to the mass of the surface treatment liquid being 0.000100% by mass or more and 0.330000% by mass or less.

2. The surface treatment liquid according to claim 1, wherein a ratio of a total mass of the propylene glycol monoalkyl ether and the propylene glycol monoacetate to the mass of the silylation agent is 1.5×10⁻⁵ or more and 6×10⁻² or less.

3. The surface treatment liquid according to claim 1, wherein a ratio of the mass of the water to the mass of the silylation agent is 5.00×10⁻⁶ or more and 2.0×10⁻² or less.

4. The surface treatment liquid according to claim 1, wherein the silylation agent comprises a compound represented by the following formula (1): 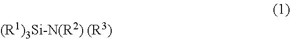
wherein, in formula (1), R¹ is a hydrogen atom, a halogen atom or an organic group, plural R¹ may be the same or different, the total number of carbon atoms in three R¹ is 1 or more, R² is a hydrogen atom or a chain hydrocarbon group, R³ is a hydrogen atom, a chain hydrocarbon group or a nonaromatic ring group, and R² and R³ may be bonded to each other to form a ring.

5. A surface treatment method comprising bringing the surface treatment liquid according to claim 1 into contact with a surface of a substrate to treat the surface of the substrate.
